(19) United States
(12) Patent Application Publication
(10) Pub. No.: US 2025/0317111 A1
(43) Pub. Date: Oct. 9, 2025

(54) RADIO FREQUENCY AMPLIFIER

(71) Applicant: STMicroelectronics International N.V., Geneva (CH)

(72) Inventors: Jocelyn Roux, Crolles (FR); Marc Margalef Rovira, Crolles (FR); Frederic Paillardet, Crolles (FR)

(21) Appl. No.: 19/098,123

(22) Filed: Apr. 2, 2025

(30) Foreign Application Priority Data
Apr. 3, 2024 (FR) FR2403403

(51) Int. Cl. H03F 3/195; H03F 1/02; H03F 1/56; H03F 3/45

(52) U.S. Cl. CPC H03F 3/195; H03F 1/0211; H03F 1/56; H03F 3/45273; H03F 2200/451

(57) ABSTRACT

The present description concerns an amplifier. A first transistor couples a first input node to a first output node. A second transistor couples a second input node to a second output node. The control terminals of the first and second transistors are connected. A third transistor has a control terminal connected to the first input node and a conduction terminal connected to the second output node. A fourth transistor has a control terminal connected to the second input node and a conduction terminal connected to the first output node. A circuit controls a current through the first and second transistors. A circuit delivers a control signal to the control terminals of the first and second transistors.

### CROSS REFERENCE TO RELATED APPLICATIONS

This application claims the priority benefit of French Patent Application No. 24/03403 filed on Apr. 3, 2024, entitled “Amplificateur radiofréquence,” which is hereby incorporated by reference to the maximum extent allowable by law.

### TECHNICAL FIELD

The present disclosure generally concerns electronic circuits, for example integrated electronic circuits, and, more particularly, radio frequency circuits configured to operate at frequencies for example in the range from 3 kHz to 300 GHz, preferably from 1 GHz to 100 GHz.

### BACKGROUND

Many radio frequency electronic circuits comprise radio frequency amplifiers configured to receive a radio frequency signal between two input nodes of the amplifier, and to deliver a corresponding amplified radio frequency signal between two output nodes of the amplifier.

### BRIEF SUMMARY

There exists a need to overcome all or part of the disadvantages of known radio frequency amplifiers.

For example, it would be desirable to have a radio frequency amplifier in which the gain and the input impedance of the amplifier can be set independently of each other.

For example, it would be desirable to have a radio frequency amplifier adapted to low-voltage applications, for example applications where the amplifier receives a nominal power supply voltage substantially equal to 1.8 V.

For example, it would be desirable to have a radio frequency amplifier having good stability conditions.

For example, it would be desirable to have a radio frequency amplifier exhibiting a good isolation between its two input nodes and its two output nodes.

An embodiment overcomes all or part of the disadvantages of known radio frequency amplifiers.

An embodiment provides an amplifier comprising:
a first input node and a second input node;
a first output node and a second output node;
a first transistor coupling the first input node to the first output node;
a second transistor identical to the first one, coupling the second input node to the second output node, the first and second transistors having their control terminals connected to each other;
a third transistor having a control terminal connected to the first input node and a first conduction terminal connected to the second output node;
a fourth transistor identical to the third one, having a control terminal connected to the second input node and a first conduction terminal connected to the first output node;
a first circuit configured to control a current flowing through the first and second transistors; and
a second circuit configured to control a control signal applied to the control terminals of the first and second transistors.

According to an embodiment, a ratio of a capacitance value between the conduction terminals of each of the first and second transistors to a capacitance value between the control terminal and the first conduction terminal of each of the third and fourth transistors is in the range from 0.8 to 1.2, preferably from 0.9 to 1.1, for example equal to 1.

According to an embodiment, each of the third and fourth transistors has a second conduction terminal connected to a node of application of a first power supply potential; and each of the first and second output nodes is coupled to a node of application of a second power supply potential.

According to an embodiment, a first inductor couples the first output node to the node of application of the second power supply potential, and a second inductor couples the second output node to the node of application of the second power supply potential.

According to an embodiment, the first and second inductors form a primary winding of a transformer.

According to an embodiment, a capacitor has a first terminal connected to a node of connection of the control terminals of the first and second transistors to each other.

According to an embodiment, the capacitor has a second terminal connected to the node of application of the first power supply potential.

According to an embodiment, the amplifier comprises a summing node configured to receive the sum of the currents flowing through the first and second transistors, the first and second input nodes each being coupled to the summing node.

According to an embodiment, a third inductor couples the first input node to the summing node and a fourth inductor couples the second input node to the summing node.

According to an embodiment, the third and fourth inductors form a secondary winding of a transformer.

According to an embodiment: the first circuit comprises a transistor connected between the summing node and the node of application of the first power supply potential; the first circuit comprises a control circuit configured to deliver, to a control terminal of the transistor, a signal determining the value of the current in the transistor; and the transistor connected between the summing node and the node of application of the first power supply potential is, preferably, twice as large as each of the first and second transistors.

According to an embodiment, the control circuit of the first circuit comprises a transistor and a current source series-connected between the nodes of application of the first and second power supply potentials, the transistor being mirror-assembled with the transistor connected between the summing node and the node of application of the first power supply potential.

According to an embodiment, the second circuit comprises: an error amplifier having a first input connected to the summing node and an output coupled to the control terminals of the first and second transistors so as to apply thereto the control signal of the first and second transistors; and a control circuit configured to deliver a set point signal to the second input of the error amplifier.

According to an embodiment, the control circuit of the second circuit comprises a current source and a transistor series-connected between the nodes of application of the first and second power supply potentials, the transistor having a control terminal connected to the second input of the error amplifier and to a node of connection of the transistor to the current source.

According to an embodiment: a dimension ratio between the transistor of the control circuit of the first circuit and the transistor connected between the summing node and the node of application of the first power supply potential determines, with a value of the current of the current source of the control circuit of the first circuit, a value of the current in each of the first and second transistors; and a dimension ratio between the transistor of the control circuit of the second circuit and the transistor connected between the summing node and the node of application of the first power supply potential determines, with a value of the current of the current source of the control circuit of the second circuit, a value of a control signal of each of the first and second transistors.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, schematically and partly in the form of blocks, an example of embodiment of a radio frequency amplifier;

FIG. 2 shows, schematically and partly in the form of blocks, a more detailed example of embodiment of a radio frequency amplifier;

FIG. 3 schematically shows an example of embodiment of a portion of a circuit of the amplifier of FIG. 2;

FIG. 4 schematically shows an example of embodiment of a portion of another circuit of the amplifier of FIG. 2;

FIG. 5 illustrates by means of curves a setting of the gain of the amplifier of FIGS. 1 and 2;

FIG. 6 illustrates by means of curves the setting of the input impedance of the amplifier of FIGS. 1 and 2; and

FIG. 7 illustrates by means of curves the isolation between the input nodes and the output nodes and the stability of the amplifier of FIGS. 1 and 2.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the various known circuits, applications, and electronic systems in which a radio frequency amplifier is implemented have not been detailed, the described embodiments and variants being compatible with these known circuits, applications and electronic systems.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

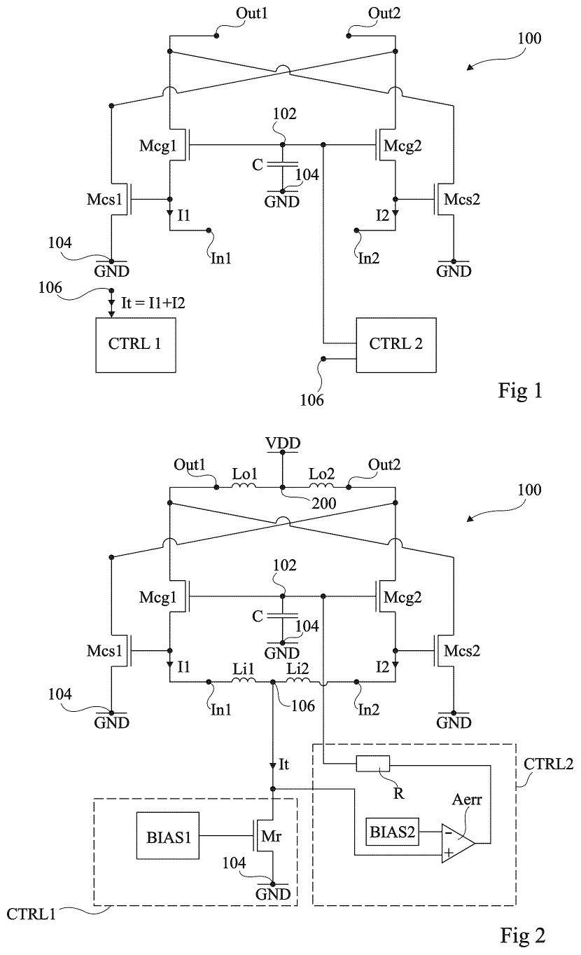

FIG. 1 shows, schematically and partly in the form of blocks, an example of embodiment of a radio frequency amplifier 100.

Amplifier 100 comprises two input nodes In1 and In2. Amplifier 100 is configured to receive an input signal to be amplified between nodes In1 and In2. For example, the input signal applied between nodes In1 and In2 is a differential signal.

Amplifier 100 further comprises two output nodes Out1 and Out2. Amplifier 100 is configured to deliver an amplified output signal between nodes Out1 and Out2. For example, the output signal available between nodes Out1 and Out2 is a differential signal.

Amplifier 100 comprises a pair of identical transistors Mcg1 and Mcg2.

In this example, transistors Mcg1 and Mcg2 are MOS (Metal Oxide Semiconductor) transistors. In this example, transistors Mcg1 and Mcg2 are each assembled with a common gate.

Amplifier 100 is for example supplied with a power supply voltage defined by a difference between a first power supply potential GND, for example the ground, and a second power supply potential VDD. In this example, potential VDD is positive with respect to the first power supply potential, and transistors Mcg1 and Mcg2 then have an N channel.

Transistor Mcg1 couples node In1 to node Out1. For example, transistor Mcg1 has a first conduction terminal, for example its drain, coupled, preferably connected, to node Out1 and a second conduction terminal, for example its source, coupled, preferably connected, to node In1.

Symmetrically, transistor Mcg2 couples node In2 to node Out2. For example, transistor Mcg2 has a first conduction terminal, for example its drain, coupled, preferably connected, to node Out2 and a second conduction terminal, for example its source, coupled, preferably connected, to node In2.

Transistors Mcg1 and Mcg2 are identically controlled by a control circuit CTRL2. Thus, according to an embodiment, transistors Mcg1 and Mcg2 have their control terminals, for example their gates, connected to each other.

Preferably, a capacitor C, for example a smoothing capacitor, is connected to a node 102 of connection of the control terminals of transistors Mcg1 and Mcg2 to each other. For example, capacitor C has a terminal connected to node 102, the other terminal of capacitor C being, for example, connected to a node 104 configured to receive the first power supply potential GND.

Amplifier 100 comprises another pair of identical transistors Mcs1 and Mcs2.

Preferably, transistors Mcs1 and Mcs2 are transistors of the same technology as transistors Mcg1 and Mcg2, that is, MOS in this example.

Further, transistors Mcs1 and Mcs2 are transistors of the same type as transistors Mcg1 and Mcg2, that is, N-channel MOS transistors in this example.

In this example, transistors Mcs1 and Mcs2 are each assembled with a common source.

Transistor Mcs1 has a control terminal, for example its gate, connected to node In1, or, in other words, to the second conduction terminal of transistor Mcg1. Further, transistor Mcs1 has a first conduction terminal, for example its source, connected to node 104.

Symmetrically, transistor Mcs2 has a control terminal, for example its gate, connected to node In2, or, in other words, to the second conduction terminal of transistor Mcg2. Further, transistor Mcs2 has a first conduction terminal, for example its source, connected to node 104.

Transistors Mcs1 and Mcs2 have their second conduction terminals, for example their drains, coupled to respective nodes Out2 and Out1. For example, the second conduction terminal of transistor Mcs1 is connected to node Out2, the second conduction terminal of transistor Mcs2 being connected to node In1.

Amplifier 100 further comprises a circuit CTRL1. Circuit CTRL1 is configured to control a current I1, respectively I2, flowing through transistor Mcg1, respectively Mcg2. Currents I1 and I2 are, in practice, direct currents (DC), or, in other words, bias currents. More particularly, amplifier 100 and its circuit CTRL1 are configured so that currents I1 and I2 are equal.

For example, amplifier 100 is configured so that MOS transistors Mcs1, Mcs2, Mcg1, and Mcg2 are biased in their saturation areas.

For a given value of currents I1 and I2 controlled by circuit CTRL1, a change in the value of the control signal applied to the control terminals of transistors Mcg1 and Mcg2 by circuit CTRL2 causes a change in the gain of the amplifier. Indeed, the change of the control signal of transistors Mcg1 and Mcg2 for a given value of currents I1, I2 causes a change in the signal at the control terminal of transistors Mcs1 and Mcs2, and thus a change in the amplifier gain. This change in the gain of amplifier 100 does not cause a significant change in the input impedance of amplifier 100. For example, for a 5-dB change in the gain of amplifier 100, the input impedance of amplifier 100 is changed by less than 50 ohms, for example by less than 30 ohms.

As an example, circuit CTRL2 regulates the control signal of transistors Mcg1 and Mcg2 to a value determined by a target value of the amplifier gain.

Symmetrically, for a given value of the control signal applied to the control terminals of transistors Mcg1 and Mcg2 by circuit CTRL2, a change in the value of currents I1 and I2 by circuit CTRL1 results in a change in the input impedance of amplifier 100. This change in the input impedance of amplifier 100 does not cause a significant change in the gain of amplifier 100. For example, for a change by a factor 2 of the input impedance of amplifier 100, the gain of amplifier 100 is modified by less than 2 dB, for example by less than 1 dB.

As an example, circuit CTRL1 regulates currents I1 and I2 to a value determined by a target input impedance value of the amplifier.

Amplifier 100 thus allows an independent setting of its gain and of its input impedance.

According to an embodiment, nodes Out1 and Out2 are each coupled to a node (not shown in FIG. 1) of application of potential VDD.

As an example, node Out1 is coupled to potential VDD by an inductor, and node Out2 is coupled to potential VDD by another inductor.

As an example, these two inductors may form the primary winding of a transformer configured to receive the output signal of the amplifier.

As another example, the two inductors do not form part of a transformer, and each of nodes Out1 and Out2 is further coupled to node 104 via a corresponding capacitor. In this case, two AC (“Alternating Current”) components of a differential output signal may be received on these two capacitors.

As another example, each of nodes Out1 and Out2 may be coupled to potential VDD so as to implement a DC coupling of each of nodes Out1 and Out2 with this potential VDD.

Due to the fact that transistors Mcs1 and Mcg1 are not series-connected between potentials VDD and GND, and, symmetrically, that transistors Mcs2 and Mcg2 are not series-connected between potentials VDD and GND, these transistors may remain biased in their saturation areas with lower potential values VDD than if these transistors had been series-connected. Thus, amplifier 100 may be used in low-voltage applications.

According to an embodiment, transistors Mcg1 and Mcs2 are configured so that the ratio Cr of the capacitance between the conduction terminals of transistor Mcg1, in practice an intrinsic capacitance of transistor Mcg1, to the capacitance between the control terminal and the second conduction terminal of transistor Mcs2, corresponding in practice to an intrinsic capacitance of transistor Mcs2, is in the range from 0.8 to 1.2, preferably from 0.9 to 1.1, for example equal to 1. This enables to ensure good stability properties for amplifier 100 and, further, a good isolation between its input nodes In1 and In2 and its output nodes Out1 and Out1. For example, this enables to obtain a factor K greater than 4, for example greater than 10 when ratio Cr is equal to 1, with

$$K = ( 1 - \sqrt{\vert S 11 \vert} - \sqrt{\vert S 22 \vert} + \sqrt{\vert S 11 * S 22 - S 12 * S 21 \vert} ) / ( 2 * \vert S 12 \vert ⋆ \vert S 21 \vert )$$

where S11, S22, S12, and S21 are the S parameters of amplifier 100. For example, this results in a power isolation S12 in dB lower than −35 dB, for example lower than −44 dB when ratio Cr is equal to 1.

In practice, selecting a ratio Cr within the above ranges, preferably equal to 1, enables to implement a neutrodyning in amplifier 100 without the need for coupling capacitors and capacitor-assembled transistors, and thus without increasing the surface area of the amplifier. Advantage is here taken of the intrinsic capacitances of transistors Mcs1, Mcs2, Mcg1, Mcg2.

According to an embodiment, nodes In1 and In2 are each coupled to a node 106 of amplifier 100. Node 106 is a current summing node, configured to receive the sum It of currents I1 and I2. Preferably, nodes In1 and In2 are not directly connected to node 106.

As an example, node In1 is coupled to node 106 by an inductor, and node In2 is coupled to node 106 by another inductor.

As an example, these two inductors may form the secondary winding of a transformer configured to apply the input signal of the amplifier.

As another example, the two inductors do not form part of a transformer, and each of nodes In1 and In2 is coupled to node 104 by a corresponding capacitor. In this case, two AC (“Alternating Current”) components of a differential input signal may be applied to these two capacitors.

According to an embodiment, circuit CTRL1 is connected to node 106 and is configured to control the value of current It so as to control the value of currents I1 and I2 to a set point value determining the value of the input impedance of amplifier 100. As an example, circuit CTRL1 couples node 106 to node 104.

Preferably, node 106 is also a bias node configured to receive, for example from circuit CTRL1, a DC bias potential.

As a variant (not shown), circuit CTRL1 may be configured to individually (or independently) control currents I1 and I2 in transistors Mcg1 and Mcg2, so that these currents are equal.

According to an embodiment, circuit CTRL2 is connected to node 106 and is configured to control, for a given value of currents I1, I2, and thus It, the control signal of transistors Mcg1 and Mcg2 so as to control, for each of transistors Mcs1 and Mcs2, the value of the control signal received by this transistor, and thus the value of the amplifier gain.

As an example, circuit CTRL2 is connected to node 106 to receive the potential of node 106, and is configured to control transistors Mcg1 and Mcg2 so as to regulate the potential of node 106 to a control value determining the value of the amplifier gain.

FIG. 2 shows, schematically and partly in the form of blocks, a more detailed example of embodiment of radio frequency amplifier 100.

The amplifier 100 of FIG. 2 has many elements in common with the amplifier 100 of FIG. 1, and only the differences between these amplifiers are here highlighted. Thus, unless otherwise indicated, all that has been indicated in relation with FIG. 1 applies in FIG. 2.

In the example of amplifier 100 of FIG. 2, node Out1, respectively Out2, is coupled to a node 200 of application of potential VDD by an inductor Lo1, respectively Lo2. Inductors Lo1 and Lo2 form, for example, the primary winding of a transformer receiving the output signal of amplifier 100.

In the example of amplifier 100 of FIG. 2, node In1, respectively In2, is coupled to node 106 by an inductor Li1, respectively Li2. Inductors Li1 and Li2 form, for example, the secondary winding of a transformer delivering the input signal of amplifier 100.

In the example of embodiment of FIG. 2, the circuit CTRL1 of amplifier 100 comprises a transistor Mr connected, by its conduction terminals, between nodes 106 and 104.

Preferably, transistor Mr is of the same technology as transistors Mcg1 and Mcg2, and is, for example, a MOS transistor when these transistors Mcg1 and Mcg2 are MOS transistors.

Preferably, the transistor is of the same type as transistors Mcg1 and Mcg2, and is, for example, an N-channel MOS transistor when these transistors Mcg1 and Mcg2 are N-channel MOS transistors.

For example, transistor Mr has a first conduction terminal, for example, its source, coupled, preferably connected, to node 104, and a second conduction terminal, for example its drain, coupled, preferably connected, to node 106.

Preferably, transistor Mr is twice as large as transistors Mcg1 and Mcg2.

In this example of embodiment, circuit CTRL1 further comprises a circuit BIAS1 for controlling transistor Mr. Circuit BIAS1 is configured to deliver a control signal determining the value of the current It in transistor Mr, and thus the value of the currents I1 and I2 in the respective transistors Mcg1 and Mcg2. As an example, the value of the signal supplied by circuit BIAS to the control terminal of transistor Mr is determined by a target input impedance value of the amplifier.

Circuit CTRL2 is configured to regulate the DC potential of node 106, or, in other words, the DC potentials of nodes In1 and In2, to a set point value determining the gain of amplifier 100. In the example of embodiment of FIG. 2, circuit CTRL2 comprises an error amplifier Aerr. Amplifier Aerr has a first input, for example non-inverting (+), coupled, preferably connected, to node 106. Circuit CTRL2 further comprises a control circuit BIAS2 configured to deliver a set point signal to the second, for example inverting (−), input of error amplifier Aerr. The output of error amplifier Aerr determines the value of the control signal delivered to the control terminals of transistors Mcg1, Mcg2. For example, the output of error amplifier Aerr is coupled to node 102, for example via a resistive element R as shown in the example of FIG. 2.

It should be noted that the implementation of circuit CRTL1 such as described in relation with FIG. 2 is independent of the implementation of circuit CTRL2 such as described in relation with FIG. 2. Thus, circuit CTRL1 may be implemented as described hereabove without for circuit CTRL2 to be implemented as described hereabove, and vice versa.

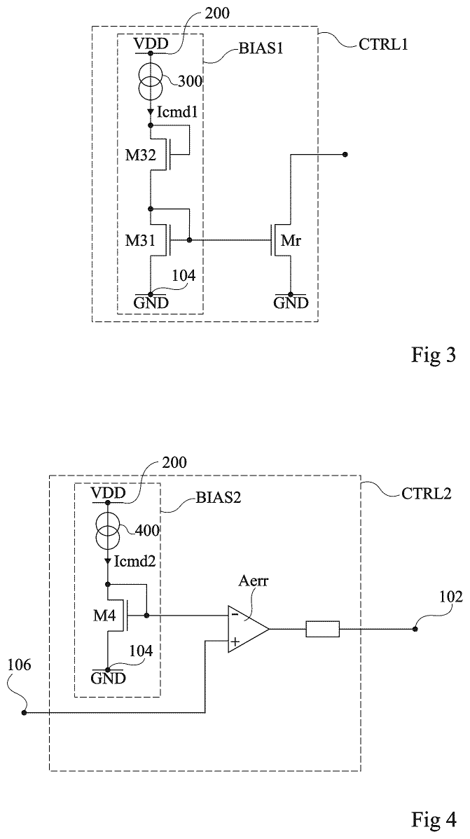

FIG. 3 schematically illustrates an example of the circuit BIAS1 of the circuit CTRL1 of the amplifier 100 of FIG. 2, it being understood that those skilled in the art will be capable of providing other implementations of this circuit BIAS1, and more generally, of circuit CTRL1.

In this example, circuit BIAS1 comprises a current source 300 and a transistor M31 series-connected between nodes 104 and 200. Transistor M31 is mirror-assembled to transistor Mr. For example, transistor M31 has a first conduction terminal connected to node 104, a second conduction terminal coupled to current source 300, and a control terminal connected to its second conduction terminal.

Transistor M31 is of the same technology and type as transistor Mr, and is, in this example, an N-channel MOS transistor. For example, its source is connected to node 104 and its drain is coupled to current source 300 and connected to the gate of transistor M31.

In the example of FIG. 3, transistor M31 is coupled to current source 300 by a diode-connected transistor M32. Transistor M32 is preferably of the same technology and of the same type as transistor M31, and is, in this example, an N-channel MOS transistor. For example, a first conduction terminal of transistor M32, in this example its source, is connected to the second conduction terminal of transistor M31, in this example its drain, and a second conduction terminal of transistor M32, for example its drain, is connected to a terminal of current source 300, the other terminal of current source 300 being connected to node 200.

Current source 300 is configured to deliver a control current Icmd1. The value of current Icmd1 determines, with a dimension ratio of transistors M31 and Mr, the value of currents I1 and 12, and thus the input impedance of amplifier 100. As an example, circuit BIAS1 is configured so that current It is equal to A times current Icmd1, with A a positive factor, and the ratio of the dimensions of transistor M31 to the ratio of the dimensions of transistor Mr is equal to A. For example, when transistor Mr is twice as large as each of transistors Mcg1 and Mcg2, transistor M31 is 2A times as large as each of transistors Mcg1 and Mcg2.

FIG. 4 schematically shows an example of embodiment of the circuit BIAS2 of the circuit CTRL2 of the amplifier 100 of FIG. 2, it being understood that those skilled in the art will be capable of providing other implementations of this circuit BIAS2, and more generally, of circuit CTRL2.

In this example of embodiment, circuit BIAS2 comprises a current source 400 and a transistor M4 series-connected between nodes 104 and 200. Transistor M4 has a control terminal connected to the second, for example inverting (−), input of error amplifier Aerr. Further, transistor M4 is diode-connected, and has its control terminal connected to a node connecting transistor M4 to current source 400.

Preferably, transistor M4 is of the same technology and of the same type as transistor Mr, and is, in this example, an N-channel MOS transistor. For example, its source is connected to node 104 and its drain is coupled, for example connected, to the current source 400 and to the gate of transistor M4.

Current source 400 is configured to deliver a control current Icmd2. The value of current Icmd2 determines, together with the sizing of transistor M4, the value of the set point signal delivered to amplifier Aerr, or, more generally, the value of the signal for controlling transistors Mcg1 and Mgc2, and thus the gain of amplifier 100.

For example, when circuit CTRL1 comprises transistor Mr between nodes 106 and 104, a dimension ratio between transistor M4 and transistor Mr determines, with a value of current Icmd2, a value of a control signal for each of transistors Mcg1 and Mcg2, and thus, for a given value of currents I1 and I2, a value of a control signal for each of transistors Mcs1 and Mcs2. As an example, circuit BIAS2 is configured so that the potential of the node connecting transistor M4 to current source 400 determines the value of the potential of node 106.

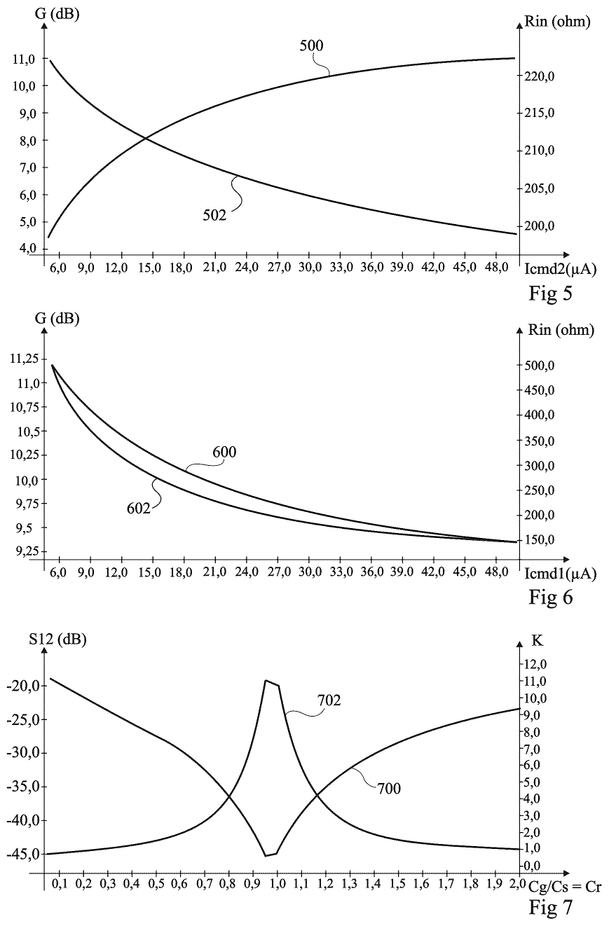

FIG. 5 illustrates by means of curves 500 and 502 an example of the setting of the gain of amplifier 100. In this example, curves 500 and 502 are obtained with circuits CTRL1 and CTRL2 implemented as described in relation with FIGS. 2 to 4, in particular as concerns circuits BIAS1 and BIAS2.

Curve 500 illustrates the variation of the gain G, in dB, of amplifier 100 as a function of a set point value, this set point value here corresponding to the value of current Icmd2, in μA. Curve 502 illustrates the variation of the input impedance Rin, in ohms, of amplifier 100 as a function of a set point value, here the value of current Icmd2.

Curve 500 shows that, by varying the set point value of circuit CTRL2, that is, here the value of current Icmd2, for example between 6 μA and 48 μA, it is possible to set the value of gain G, for example to vary the value of gain G between 4.5 dB and 11 dB.

Further, curve 502 shows that this adjustment of gain G by circuit CTRL2 does not significantly modify the value of input impedance Rin. In other words, when gain G varies by one dB, input impedance Rin varies by less than 10%, preferably by less than 5%.

For example, when the set point value of circuit CTRL2, that is, the value of current Icmd2, varies between 6 μA and 48 μA, the value of gain G varies between 4.5 dB and 11 dB, while input impedance Rin remains in the range from 225 to 198 ohms.

FIG. 6 illustrates by means of curves 600 and 602 an example of the setting of the input impedance Rin of amplifier 100. In this example, curves 600 and 602 are obtained with circuits CTRL1 and CTRL2 implemented as described in relation with FIGS. 2 to 4, in particular as concerns circuits BIAS1 and BIAS2.

Curve 600 illustrates the variation of the gain G, in dB, of amplifier 100 as a function of a set point value, this set point value here corresponding to the value of current Icmd1, in μA. Curve 602 illustrates the variation of the input impedance Rin, in ohms, of amplifier 100 as a function of a set point value, here the value of current Icmd1.

Curve 602 shows that, by varying the set point value of circuit CTRL1, that is, here the value of current Icmd1, for example between 6 μA and 48 μA, it is possible to set the value of input impedance Rin, for example to vary the value of impedance Rin between 150 and 500 ohms.

Further, curve 600 shows that this setting of impedance Rin by circuit CTRL1 does not significantly alter the value of gain G. For example, when impedance Rin varies by a factor of 2, gain G varies by less than 2 dB, preferably by less than 1 dB. In other words, when impedance Rin varies, for example, by 100 ohms, gain G varies by less than 1 dB.

For example, when the set point value of circuit CTRL1, that is, the value of current Icmd1, varies between 6 μA and 48 μA, the value of input impedance Rin varies between 150 and 500 ohms, while gain G remains in the range from 9.25 to 11.25 dB.

FIG. 7 illustrates by means of curves the variation of the power isolation S12, in dB, between nodes In1, In2 and nodes Out1, Out2 (curve 700) and of the stability K of amplifier 100 (curve 702), as a function of the variation of the ratio of the intrinsic capacitance Cg between the source and the drain of transistor Mcg1, respectively Mcg2, to the intrinsic capacitance Cs between the gate and the drain of transistor Mcs1, respectively Mcs2.

Curves 700 and 702 show that the closer ratio Cg/Cs is to 1, the better the stability and the isolation in amplifier 100.

For example, curves 700 and 702 show that, for a ratio Cg/Cs in the range from 0.8 to 1.2, isolation S12 is lower than −35 dB, that is, has negative values greater, in absolute value, than 35, and that the value of stability factor K is greater than 4.

For example, curves 700 and 702 show that, for a ratio Cg/Cs in the range from 0.8 to 1.1, isolation S12, is lower than −42 dB, that is, has negative values greater, in absolute value, than 42, and that the value of stability factor K is greater than 7.5.

For example, curves 700 and 702 show that, for a ratio Cg/Cs equal to 1, isolation S12 is equal to −45 dB and that the value of stability factor K is equal to 10.5.

Thus, as previously indicated, transistors Mcg1, Mcg2, Mcs1, and Mcs2 are configured so that the ratio Cr of the intrinsic capacitance between the conduction terminals of each of transistors Mcg1, Mcg2 to the intrinsic capacitance between the control terminal and the second conduction terminal of each of transistors Mcs1 and Mcs2 is in the range from 0.8 to 1.2, preferably from 0.9 to 1.1, for example equal to 1.

Various embodiments and variants have been described. Those skilled in the art will understand that certain features of these various embodiments and variants may be combined, and other variants will occur to those skilled in the art.

In particular, in the described examples, the transistors are in MOS technology and are of N-channel type. However, those skilled in the art will be capable of adapting the above description of these examples to the case where potential VDD is negative with respect to potential GND, for example by replacing all N-channel MOS transistors with P-channel MOS transistors.

More generally, those skilled in the art will be capable of adapting the above description of examples in which the transistors are in MOS technology to cases where the transistors are in bipolar technology, for example all of PNP or all of NPN type according to whether potential VDD is positive or negative with respect to potential GND, or even to transistors in BiCMOS technology.

Finally, the practical implementation of the described embodiments and variants is within the abilities of those skilled in the art based on the functional indications given hereabove.

That which is claimed:

1. An amplifier comprising:
a first input node and a second input node;
a first output node and a second output node;
a first transistor coupling the first input node to the first output node;
a second transistor identical to the first transistor, coupling the second input node to the second output node, the first and second transistors having their control terminals connected to each other;
a third transistor having a control terminal connected to the first input node and a first conduction terminal connected to the second output node;
a fourth transistor identical to the third transistor, having a control terminal connected to the second input node and a first conduction terminal connected to the first output node;
a first circuit configured to control a current flowing through the first and second transistors; and
a second circuit configured to control a control signal applied to the control terminals of the first and second transistors.

2. The amplifier according to claim 1, wherein a ratio of a capacitance value between the conduction terminals of each of the first and second transistors to a capacitance value between the control terminal and the first conduction terminal of each of the third and fourth transistors is in a range from 0.8 to 1.2.

3. The amplifier according to claim 2, wherein the ratio of the capacitance value between the conduction terminals of each of the first and second transistors to the capacitance value between the control terminal and the first conduction terminal of each of the third and fourth transistors is in a range from 0.9 to 1.1.

4. The amplifier according to claim 2, wherein the ratio of the capacitance value between the conduction terminals of each of the first and second transistors to the capacitance value between the control terminal and the first conduction terminal of each of the third and fourth transistors is equal to 1.

5. The amplifier according to claim 1, wherein each of the third and fourth transistors has a second conduction terminal connected to a node of application of a first power supply potential; and
wherein each of the first and second output nodes is coupled to a node of application of a second power supply potential.

6. The amplifier according to claim 5, wherein a first inductance couples the first output node to the node of application of the second power supply potential, and a second inductance couples the second output node to the node of application of the second power supply potential.

7. The amplifier according to claim 6, wherein the first and second inductors form a primary winding of a transformer.

8. The amplifier according to claim 5, wherein a capacitor has a first terminal connected to a node of connection of the control terminals of the first and second transistors to each other.

9. The amplifier according to claim 8, wherein the capacitor has a second terminal connected to the node of application of the first power supply potential.

10. The amplifier according to claim 5, wherein the amplifier comprises a summing node configured to receive a sum of the currents flowing through the first and second transistors, the first and second input nodes being each coupled to the summing node.

11. The amplifier according to claim 10, wherein a third inductor couples the first input node to the summing node and a fourth inductor couples the second input node to the summing node.

12. The amplifier according to claim 11, wherein the third and fourth inductors form a secondary winding of a transformer.

13. The amplifier according to claim 10, wherein the first circuit comprises a transistor connected between the summing node and the node of application of the first power supply potential;
wherein the first circuit comprises a control circuit configured to deliver, to a control terminal of the transistor, a signal determining a value of the current in the transistor; and
wherein the transistor connected between the summing node and the node of application of the first power supply potential is twice as large as each of the first and second transistors.

14. The amplifier according to claim 13, wherein the control circuit of the first circuit comprises a transistor and a current source series-connected between the nodes of application of the first and second power supply potentials, the transistor being mirror-assembled with the transistor connected between the summing node and the node of application of the first power supply potential.

15. The amplifier according to claim 10, wherein the second circuit comprises:
an error amplifier having a first input connected to the summing node and an output coupled to the control terminals of the first and second transistors so as to apply thereto the control signal of the first and second transistors; and
a control circuit configured to deliver a set point signal to a second input of the error amplifier.

16. The amplifier according to claim 15, wherein the control circuit of the second circuit comprises a current source and a transistor series-connected between the nodes of application of the first and second power supply potentials, the transistor having a control terminal connected to the second input of the error amplifier and to a node of connection of the transistor to the current source.

17. The amplifier according to claim 16, wherein the first circuit comprises a transistor connected between the summing node and the node of application of the first power supply potential;
wherein the first circuit comprises a control circuit configured to deliver, to a control terminal of the transistor, a signal determining the value of the current in the transistor;
wherein the transistor connected between the summing node and the node of application of the first power supply potential is twice as large as each of the first and second transistors;
wherein a dimension ratio between the transistor of the control circuit of the first circuit and the transistor connected between the summing node and the node of application of the first power supply potential determines, with a value of the current of the current source of the control circuit of the first circuit, a value of the current in each of the first and second transistors; and
wherein a dimension ratio between the transistor of the control circuit of the second circuit and the transistor connected between the summing node and the node of application of the first power supply potential determines, with a current value of the current source of the control circuit of the second circuit, a value of a control signal of each of the first and second transistors.
